(19) United States
(12) Patent Application Publication
(10) Pub. No.: US 2024/0377433 A1
(43) Pub. Date: Nov. 14, 2024

(54) TEST SOCKET AND PROBE WITH STEPPED COLLAR FOR SEMICONDUCTOR INTEGRATED CIRCUITS

(71) Applicant: Smiths Interconnect Americas, Inc., Kansas City, KS (US)

(72) Inventors: Jiachun Zhou, Fremont, CA (US); Zhe Yang, Suzhou, Jiangsu (CN)

(21) Appl. No.: 18/696,015

(22) PCT Filed: Sep. 26, 2022
(86) PCT No.: PCT/US2022/044678

§ 371 Date: Mar. 27, 2024

(30) Foreign Application Priority Data
Sep. 27, 2021 (CN) 202111135635.9

(51) Int. Cl. G01R 1/067; G01R 1/073; G01R 3/00

(52) U.S. Cl. CPC G01R 1/06733; G01R 1/06722; G01R 1/07314; G01R 3/00

(57) ABSTRACT

A contact probe includes a shell having a first end and an opposed second end. The shell defines an interior chamber therein and a longitudinal axis extending through the first end and the second end. The contact probe further includes a plunger partially received within the interior chamber and extending longitudinally outward of the first end. The plunger includes a tip for electrically connecting the contact probe to an external chip. The contact probe further includes a stepped collar coupled to the shell. The stepped collar includes a first step and a second step. The second step extends about the shell and the first step extends around the plunger longitudinally between the second step and the tip.

### FIELD

The field of the disclosure relates generally to a test socket for semiconductor integrated circuits and, more specifically, a test socket with a contact probe having a stepped collar for restraining lateral movement of the probe within the socket during use.

### BACKGROUND

Semiconductor integrated circuits (ICs) are produced in various packages, or chip configurations, including, for example, a quad flat no-leads (QFN) package that is common in many IC applications and is produced in large quantities. Production of ICs of any quantity generally includes testing of the ICs in a manner that simulates an end-user's application of those ICs. One manner of testing ICs is to connect each IC to a printed circuit board (PCB) that exercises the contacts and various functionalities of the IC. That PCB is sometimes referred to as a load board, and can be re-used to test many ICs. A fundamental component of the load board that enables such testing is a test socket for the IC that can be re-used many times to test large quantities of the IC. The test socket connects, both electrically and mechanically, the IC to the load board. The degree to which the test socket can be re-used is quantified by how many “cycles” it can withstand without degrading performance, e.g., signal performance. Each time an IC is inserted, or set, into the test socket is referred to as one cycle.

Generally, over the course of many cycles, electrical and mechanical properties of the contacts and structures of the test socket begin to degrade as a result of, for example, oxidation, abrasion, compression, tension, or other forms of wear. Such degradation eventually impacts integrity of the testing itself, at which point the test socket reaches the end of its useful life. For example, at least some known test systems include a plunger that extend freely out of a test socket to contact the IC. Over the course of many cycles, repeated engagement with the IC may cause bending of the plungers, resulting in poor signal connection and/or rendering the system inoperable. Accordingly, test sockets that maintain good electrical and mechanical performance for long life cycles are desired.

### BRIEF DESCRIPTION

In one aspect, a contact probe is provided. The contact probe includes a shell having a first end and an opposed second end. The shell defines an interior chamber therein and a longitudinal axis extending through the first end and the second end. The contact probe further includes a plunger partially received within the interior chamber and extending longitudinally outward of the first end. The plunger includes a tip for electrically connecting the contact probe to an external chip. The contact probe further includes a stepped collar coupled to the shell. The stepped collar includes a first step and a second step. The second step extends about the shell and the first step extends around the plunger longitudinally between the second step and the tip.

In another aspect, an electrical connector assembly is provided. The electrical connector assembly includes a socket body that includes a neck and a central portion extending within the socket body and cooperatively defining a cavity therein and a contact probe at least partially positioned within the cavity. The contact probe includes a shell that includes a first end and an opposed second end. The shell defines an interior chamber therein and a longitudinal axis extending through the first end and the second end. The contact probe further includes a plunger partially received within the interior chamber and extending longitudinally outward of the first end. The plunger includes a tip for electrically connecting the contact probe to an external chip. The contact probe further includes a stepped collar coupled to the shell. The stepped collar includes a first step sized in correspondence with the neck and a second step sized in correspondence with the central portion.

In yet another aspect, a method of forming a contact probe is provided. The method includes providing a shell including a first end and an opposed second end. The shell defines an interior chamber therein and a longitudinal axis extending through the first end and the second end. The method further includes positioning a plunger at least partially within the interior chamber. The plunger extends longitudinally outward of the first end to a tip for electrically connecting the contact probe to an external chip. The method further includes coupling a stepped collar to the shell. The stepped collar includes a first step and a second step. The second step extends about the shell and the first step extends around the plunger longitudinally between the second step and the tip.

### BRIEF DESCRIPTION OF THE DRAWINGS

FIG. 1 is an exploded perspective view of an example IC test system;

FIG. 2 is a cross-section of the test system of FIG. 1, showing an IC disconnected from the test system;

FIG. 3 is a cross-section of the test system of FIG. 1, showing the IC connected to the test system;

FIG. 4 is a perspective view of a spring probe used in the test system of FIG. 1;

FIG. 5 is an exploded view of the spring probe shown in FIG. 4; and

FIG. 6 is a cross-section of the spring probe shown in FIG. 4;

### DETAILED DESCRIPTION

Embodiments of the disclosed test socket provide a spring probe having a stepped retaining collar. The disclosed test sockets are configured to receive a flat no-leads IC package, such as a QFN IC and include probes that provide electrical connection between the IC and a load board, such as a PCB. To engage the load board with an IC under test, the IC is lowered onto the test socket making connections with spring probes extending between the IC and the load board. The spring probes each include contact plungers the IC is lowered onto for testing. A stepped collar surrounds at least a portion of the plungers to align the plungers in position for connection with the IC and limit lateral displacement of the plungers that may result over repeated cycles. The test sockets described herein further allow for spacing the spring probe from the test socket during use, generally reducing wear on the spring probe resulting from contact with the test socket, and improving signal performance.

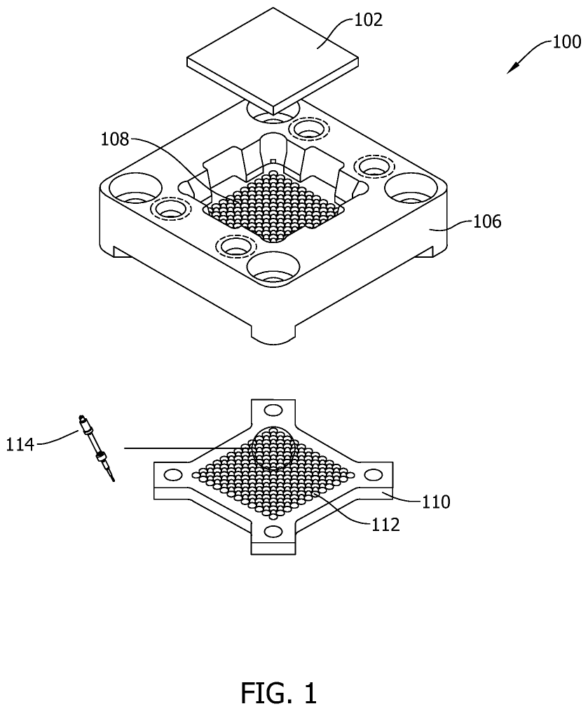

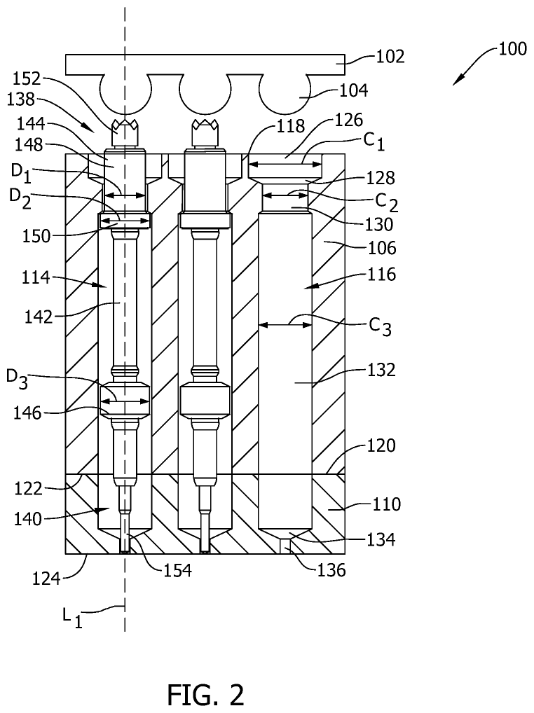

FIG. 1 is an exploded perspective view of an example test system 100 (alternatively referred to as an “electrical connector assembly” herein) for testing a semiconductor IC chip 102. IC chip 102 is one or more electronic circuits packaged into a single semiconductor chip generally including a plurality of contact pads 104 (FIG. 2) for conducting signals to and from the circuits within the package. Test system 100 includes a socket body 106 defining a first plurality of cavities 108. Test system 100 further includes a socket retainer 110 defining a second plurality of cavities 112. Socket retainer 110 is configured to be coupled to socket body 106 with spring probes 114 (broadly referred to herein as “contact probes”) extending between the cavities of socket body 106 and socket retainer 110. In particular, each of the second plurality of cavities 112 is positioned in correspondence with a respective one of the first plurality of cavities 108, such that when socket retainer 110 is coupled to socket body 106, corresponding first cavities 108 and second cavities 112 cooperatively define continuous interior cavities 116 (FIG. 2) that receive spring probe 114. In other embodiments, test system 100 includes one or more additional layers (not shown) coupled between socket retainer 110 and socket body 106. Such additional layers are more fully described in U.S. Pat. No. 8,758,066, the content of which is hereby incorporated by reference in its entirety. In the example embodiment, socket body 106 is formed of aluminum, though in other embodiments, other suitable materials may be used.

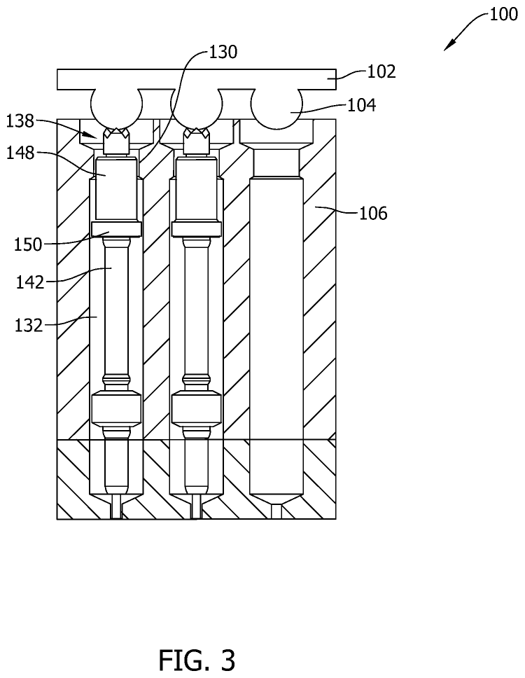

FIG. 2 is a cross sectional view of a portion of the example test system 100 shown in FIG. 1 in a first position, in which IC chip 102 is out of contact with spring probes 114. FIG. 3 is a cross sectional view of the portion of the example test system 100 shown in FIG. 2 in a second position, in which spring probes 114 are connected to IC chip 102. In the sectional views of FIGS. 2 and 3, socket body 106 and socket retainer 110 are shown sectioned and spring probes 114 are not sectioned to show the fitting of spring probes 114 within cavities 116.

In the example embodiment, each of the illustrated spring probes 114 and cavities 116 are substantially identical. A third cavity 116 is shown in FIG. 2 without a spring probe received therein to illustrate the internal construction of cavity. The spring probes 114 each define a longitudinal axis, indicated at L₁.

Referring to FIG. 2, in the example embodiment, socket body 106 is coupled to socket retainer 110 and spring probes 114 each extend continuously between first and second cavities 108, 112 (FIG. 1). Socket body 106 extends between an exterior surface 118 that faces IC chip 102 and end surface 120 facing socket retainer 110. Socket retainer 110 extends between a first or upper surface 122 and a second or lower surface 124. First surface 122 is oriented to face, and is in contact with, interior surface 120 of socket body 106. Second surface 124 is positioned opposite first surface 122.

In the example embodiment, socket retainer 110 is coupled to socket body 106 such that the cavities 108, 112 (FIG. 1) form a continuous cavity 116 sized to receive spring probes 114 therein. Cavities 116 are each defined by a rim 126, a first tapered ledge 128, a cavity neck 130, a central portion 132, a second tapered ledge 134, and a slot 136. Rim 126 is defined within exterior surface 118 of socket body 106 and extends downward from exterior surface 118 to first tapered ledge 128. The cavities 116 at rim 126 have a first diameter, indicated at C₁. First tapered ledge 128 tapers inwardly from rim 126 to cavity neck 130. Cavity neck 130 extends downwards from first tapered ledge 128 to central portion 132 and has a reduced second diameter, indicated at C₂, compared to the diameter C₁ of rim 126. Central portion 132 extends from cavity neck 130 through end surface 120 of socket body 106, into socket retainer 110, and to second tapered ledge 134. Central portion 132 has a third diameter, indicated at C₃. In the example embodiment, third diameter C₃ is greater than second diameter C₂ and less than first diameter C₁. Second tapered ledge 134 tapers inward from central portion 132 to slot 136, which extends through second surface 124 of socket retainer 110. In other embodiments, socket body 106 and socket retainer 110 may define any suitable sized cavities 116 that enable test system 100 to function as described herein.

In the example embodiment, spring probes 114 are each received within cavities 116 and include a first plunger 138, a second plunger 140, a shell 142, a stepped collar 144 (broadly referred to herein as a “first collar”), and an body collar 146 (broadly referred to herein as a “second collar”). Longitudinal axis L₁ extends through first plunger 138 and second plunger 140. Shell 142 is tubular (e.g., cylindrical or having a cross-section with a shape, such as a circular, oval, square, rectangular, or other shape). At least a portion of first and second plungers 138, 140 are disposed within shell 142, as described in greater detail below.

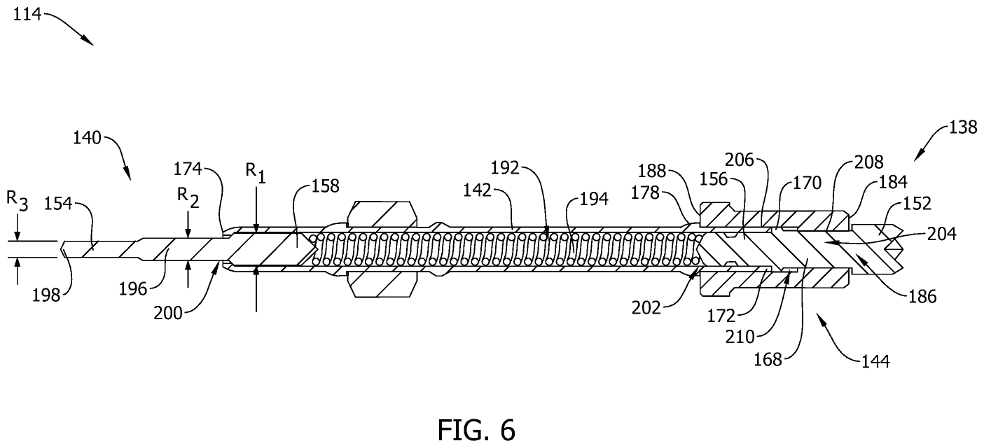

First plunger 138 includes a crown 152 that extends outwardly from the shell 142. Crown 152 is configured to contact and electrically connect to conductive pads 104 of IC chip 102. First plunger 138 is attached to the shell 142 so that first plunger 138 and the shell 142 move together. For example, first plunger 138 includes a first base portion 156 (FIG. 6) inserted into the shell 142 and attached to the shell 142 such that first plunger 138 and shell 142 move together. Second plunger 140 includes a tip portion 154 that extends outwardly from shell 142. Tip portion 154 is configured to contact and electrically connect to conductive pads (e.g., on a PCB, not shown). Second plunger 140 also includes a second base portion 158 (FIG. 6) inserted into shell 142. The end of the shell 142 that receives the second plunger 140 can be crimped to retain second base portion 156 of the second plunger 140 in the shell 142 so that second base portion 156 is slidable within the shell 142. Tip portion 154 extends outwardly from the shell 142 away from second base portion 156 and into slot 136. First plunger 138, second plunger 140, and shell 142 are made of conductive materials so that an electrical connection is formed between first plunger 138, second plunger 140, and shell 142. In particular, in the example embodiment, first plunger 138 is made of a homogenous alloy. Second plunger 140 is made of a gold-plated carbon steel. Shell 142 is made of a gold-plated copper alloy. In alternative embodiments first plunger 138, second plunger 140, and shell 142 may be made of any other suitable materials.

In the example embodiment, spring probe 114 includes stepped collar 144 coupled to shell 142 proximate first plunger 138 and body collar 146 coupled to shell 142 proximate second plunger 140. Stepped collar 144 and body collar 146 are each made of an insulative material having a low dielectric constant, such as polytetrafluoroethylene (PTFE) or other nonconductive material, such as plastic, polymer, rubber, etc. Stepped collar 144 is shaped as a stepped cylinder and includes a first step 148 and a second step 150. In other embodiments, stepped collar 144 may have any suitable shape (e.g., oval, square, rectangular, etc.)

As shown in FIG. 2, stepped collar 144 extends longitudinally between shell 142 and crown 152 and is fitted on crown 152 to surround a portion of shell 142 and first plunger 138. First step 148 has a first diameter perpendicular to the longitudinal axis L₁, indicated at D₁. Second step 150 has a second, diameter perpendicular to the longitudinal axis L₁, indicated at D₂. The second diameter D₂ is greater than the first diameter D₁. In particular, the first step 148 is sized to be received within and contact cavity neck 130 to limit lateral displacement (i.e., transverse displacement of first plunger 148 relative to the longitudinal axis L₁) during use. Second step 150 is received within and contacts central portion 132. First step 148 and second step 150 are sized in correspondence with cavity neck 130 and central portion 132, respectively. That is, in the example embodiment, the diameter D₁ of first step 148 is approximately equal to, or slightly less than, the diameter C₂ of cavity neck 130. The diameter D₂ of second step 150 is approximately equal to, or slightly less than, the diameter C₃ of central portion 132. As a result, in the example embodiment, first step 148 contacts and engages cavity neck 130 and second step 150 contacts and engages central portion 132.

Body collar 146 is fitted on shell 142 to surround a portion of shell 142. Body collar 146 is sized in correspondence with central portion 132 of cavity 116. Body collar 146 has a diameter D₃ that is approximately equal to, or slightly less than, the diameter C₃ of central portion 132. As a result, stepped collar 144 and body collar 146 align spring probe within cavities 116 such that spring probe 114, or more specifically, conductive elements of spring probe 114, such as shell 142, first plunger 138, and second plunger 140, are spaced from and do not directly contact walls of cavities 116. As a result, in some embodiments, cavities 116 may not include an insulation coating.

Referring to FIG. 3, in the example embodiment, IC chip 102 is connected to socket body 106. In particular, IC chip 102 is lowered from the first position (shown in FIG. 2) such that conductive pads 104 contact plungers 138 and longitudinally displace plungers 138, 140 and shell 142 downward within socket body 106. In the example embodiment, the engagement of first step 148 with cavity neck 130 and of second step 150 with central portion 132 limits lateral displacement of first plunger 138 when conductive pads 104 of IC chip 102 are brought into contact with first plunger 138.

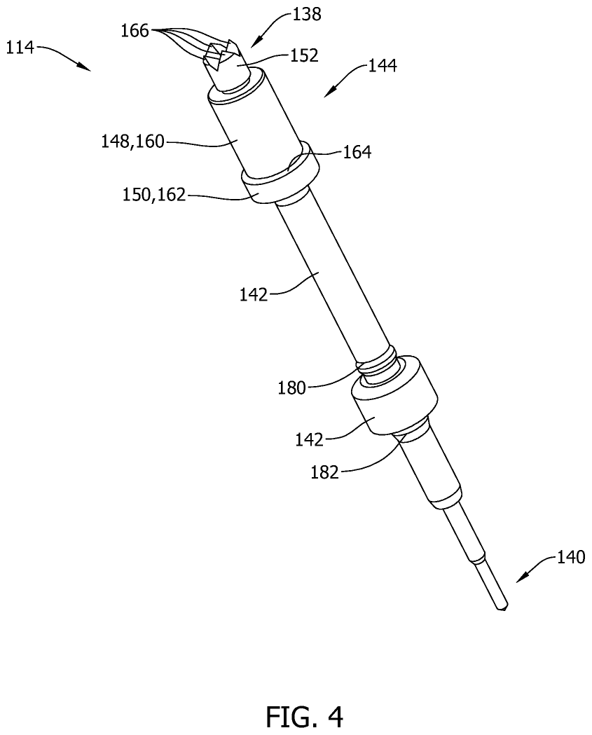

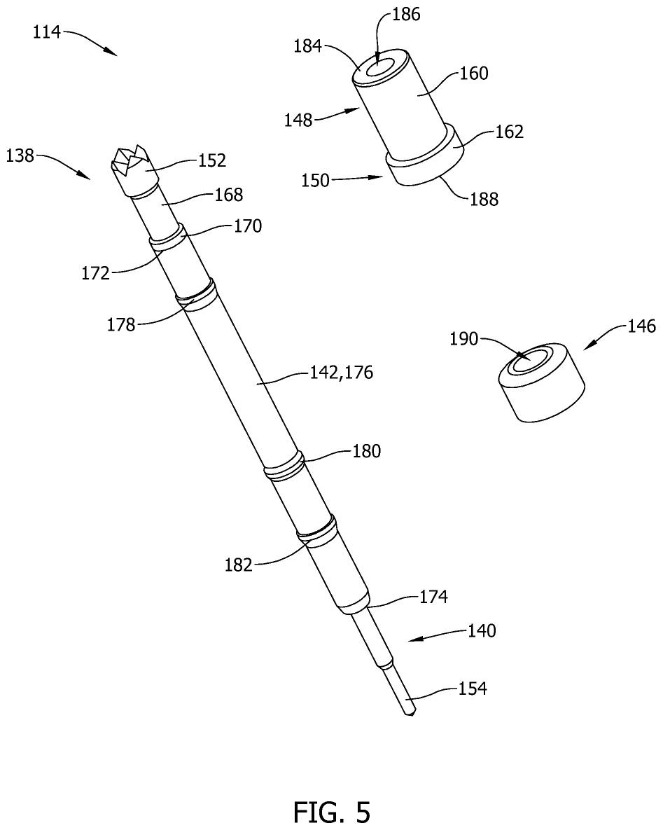

FIG. 4 is a perspective view of spring probe 114. FIG. 5 is an exploded view of spring probe 114 shown in FIG. 4.

Referring to FIG. 4, in the example embodiment, first step 148 and second step 150 are each cylindrical shaped and are sized to circumscribe first plunger 138 and shell 142. More specifically, first step 148 includes a first cylindrical outer surface 160 and second step 150 includes a second cylindrical outer surface 162. A step surface 164 extends radially (i.e., perpendicular to the longitudinal axis L₁ shown in FIG. 2) between first cylindrical outer surface 160 and second cylindrical outer surface 162. In alternative embodiments, step surface 164 is tapered and/or sloped between first cylindrical outer surface 160 and second cylindrical outer surface 162.

In the example embodiment, crown 152 includes a plurality of first contact tips 166 (e.g., four in embodiment of FIG. 4). First contact tips 166 define a distal end of spring probe 114. Referring to FIG. 5, first plunger further includes a neck 168 and a shoulder 170. Shoulder 170 contacts a first end 172 of shell 142 and limits longitudinal movement of first plunger 138 into shell 142. Neck 168 is radially recessed relative to shoulder 170 and extends from shoulder 170 to crown 152. In other embodiments, first plunger 138 may include any suitably shaped contact tip that enables spring probe 114 to function as described herein. For example, in one alternative embodiment first plunger 138 has a contact tip having a curved conical shape.

Referring to FIG. 5, in the example embodiment, shell 142 includes first end 172, a second end 174, and a generally cylindrical outer surface 176 extending between first end 172 and second end 174. Longitudinal axis L₁ (FIG. 2) extends through first end 172 and second end 174. First plunger 138 extends longitudinally outward from first end 172 and second plunger 140 extends longitudinally outward from second end 174. Shell 142 further includes a plurality of ledges 178-182 extending radially outward from outer surface 176 and extending circumferentially around outer surface 176. More specifically, shell 142 includes a first ledge 178 that is positioned to contact and engage stepped collar 144. First ledge 178 and crown 152 retain stepped collar 144 on shell 142 (e.g., as shown in FIG. 4). Shell 142 further includes a second ledge 180 and a third ledge 182. positioned longitudinally between first ledge 178 and second end 174. Second ledge 180 and third ledge 182 are spaced form one another on outer surface 176 to receive and retain body collar 146 on spring probe 114 therebetween (e.g., as shown in FIG. 4).

As shown in FIG. 5, stepped collar 144 includes a first axial or longitudinal (terms used interchangeably herein) end 184 on first step 148 and a second axial end 188 on second step 150. First axial end 184 defines a first opening 186 therein. First cylindrical outer surface 160 extends longitudinally from first axial end 184 to second step 150, or more specifically, to step surface 164 of second step 150. Body collar 146 defines a slot 190 extending therethrough. Referring back to FIG. 4, in the example embodiment, stepped collar 144 extends between shell 142 and crown 152, covering neck 168 and shoulder 170 (FIG. 5) of first plunger 138 such that crown 152 is the only exposed portion of first plunger 138. Body collar 146 is secured to shell 142 between second ledge 180 and third ledge 182.

FIG. 6 is a cross-section of the spring probe 114 shown in FIG. 4. In the example embodiment, shell 142 is generally hollow and defines a cavity 192 (alternatively referred to as an “interior chamber” herein). Spring probe 114 further includes a biasing element 194 positioned within cavity 192 coupling first plunger 138 to second plunger 140. In the example embodiment the biasing element 194 is a compression spring, though in alternative embodiments, any suitable biasing element may be used. The biasing element 194 is configured to exert a biasing force against each plunger 138, 140 to bias second plunger 140 outwardly from shell 142 and away from first plunger 138. Second plunger 140 can be depressed inwardly into the shell 142 under a force directed inward against the biasing element 194. Thus, first plunger 138 is coupled to second plunger 140 to move with shell 142, and second plunger 140 is slidable with respect to shell 142. In the example embodiment biasing element 194 is made of a gold pated carbon steel, though in alternative embodiments, any suitable materials may be used.

As shown in FIG. 6, first plunger 138 is coupled to biasing element 194 at first base portion 156 extending within shell 142. In particular, first base portion 156 extends longitudinally from biasing element 194 to shoulder 170 at first end 172 and is sized to contact shell 142. Second plunger 140 includes a second base portion 158, an intermediate portion 196 extending from base portion 158 and tip portion 154 extending from intermediate portion 196 to a second contact tip 198. Base portion 158 has a first radial thickness R₁, intermediate portion 196 has a second radial thickness R₂ that is less than first radial thickness R₁ of base portion 158, and tip portion 154 has a third radial thickness R₃ that is less than second radial thickness R₂ of intermediate portion 196. Second end 174 of shell 142 defines a cavity opening 200 in connection with cavity 192. Cavity opening 200 is sized between first thickness R₁ of base portion 158 and second thickness R₂ of intermediate portion, such that intermediate portion 196 and tip portion 154 may pass through cavity opening 200 and base portion 158 is prevented from exiting cavity 192 through cavity opening 200.

In the example embodiment, second axial end 188 of stepped collar 144 defines a second opening 202 connected to first opening 186 at first axial end 184 by a slot 204 extending longitudinally through stepped collar 144. Shell 142 extends through second opening 202 and is in fitted contact with stepped collar 144. In particular, stepped collar 144 includes a first interior surface 206 and a second interior surface 208 that cooperatively define slot 204. First interior surface 206 extends longitudinally from first axial end 184 to second interior surface 208. Second interior surface 208 extends longitudinally from first interior surface 206 to second axial end 188. First interior surface 206 extends circumferentially about neck 168 and is in fitted contact with neck 168 of first plunger 138 to restrain lateral movement of first plunger 138 during use. At least a portion of second interior surface 208 extends circumferentially about shell 142 and is in fitted contact with shell 142. In particular, in the example embodiment, second interior surface 208 extends longitudinally outward of shell 142 and shoulder 170 (i.e., to the right of the page in FIG. 6) to first interior sidewall 206. First interior surface 206 extends circumferentially about neck 168 radially inward of second interior surface 208, such that slot 204 is narrowed at first interior surface 206 compared with second interior surface 208.

As shown in FIG. 6, crown 152 is sized to extend radially outward from neck 168 and first opening 186. That is crown 152 substantially restrains outward longitudinal movement (i.e., to the right of the page in FIG. 6) of stepped collar 144. First ledge 178 is positioned to contact second axial end 188 of stepped collar 144 to restrain inward longitudinal movement (i.e., to the left of the page in FIG. 6) of stepped collar 144. As a result, stepped collar 144 is secured on spring probe 114 longitudinally between first ledge 178 and crown 152. In the example embodiment, a longitudinal gap 210 is defined between crown 152 and first axial end 184. As a result, in the example embodiment, minor longitudinal movement of stepped collar 144 is permitted. In alternative embodiments, crown 152 and first ledge 178 are each positioned in direct contact with stepped collar 144.

To assemble spring probe 114, first plunger 138, biasing element 194, and second plunger 140 may be separately connected and formed into a single assembly prior to insertion into cavity 192 of shell 142. Tip portion 154 of second plunger 140 may be inserted into cavity 192 at first end 172 and biasing element 194 and first plunger 138 may be fed with second plunger 140 into cavity 192 until second plunger 140 extends outward of opening 200 at second end 174. Stepped collar 144 is then slid over first plunger 138 (e.g., by flexing first axial end 184 to permit passage of crown 152 through first opening 186) and is secured in position between crown 152 and first ledge 178. Body collar 146 is slid over second plunger 140 and onto shell 142 between second ledge 180 and third ledge 182 in substantially the same manner as stepped collar 144. In some embodiments, collars 144, 146 are secured to shell 142 (e.g., by an adhesive). In other embodiments, spring probe 114 is assembled by any suitable process that enables spring probe 114 to function as described herein.

The technical effects of the systems and apparatuses described herein may include: (a) aligning the contact plunger in position within the test socket for contact with the IC chip; (b) reducing wear on the contact plunger resulting from lateral displacement of the contact plunger when setting the IC into the test socket; (c) reducing contact electrical resistance between test socket and spring probe by securing spring probe in the socket with the collars; and (d) improving signal quality between the IC and a PCB by insulating the spring probe from the test socket.

In the foregoing specification and the claims that follow, a number of terms are referenced that have the following meanings.

As used herein, an element or step recited in the singular and preceded with the word “a” or “an” should be understood as not excluding plural elements or steps, unless such exclusion is explicitly recited. Furthermore, references to “example implementation” or “one implementation” of the present disclosure are not intended to be interpreted as excluding the existence of additional implementations that also incorporate the recited features.

“Optional” or “optionally” means that the subsequently described event or circumstance may or may not occur, and that the description includes instances where the event occurs and instances where it does not.

Approximating language, as used herein throughout the specification and claims, may be applied to modify any quantitative representation that could permissibly vary without resulting in a change in the basic function to which it is related. Accordingly, a value modified by a term or terms, such as “about,” “approximately.” and “substantially,” are not to be limited to the precise value specified. In at least some instances, the approximating language may correspond to the precision of an instrument for measuring the value. Here, and throughout the specification and claims, range limitations may be combined or interchanged. Such ranges are identified and include all the sub-ranges contained therein unless context or language indicates otherwise.

Disjunctive language such as the phrase “at least one of X, Y, or Z,” unless specifically stated otherwise, is generally understood within the context as used to state that an item, term, etc., may be either X, Y, or Z, or any combination thereof (e.g., X, Y, and/or Z). Thus, such disjunctive language is not generally intended to, and should not, imply that certain embodiments require at least one of X, at least one of Y, or at least one of Z to each be present. Additionally, conjunctive language such as the phrase “at least one of X, Y, and Z,” unless specifically stated otherwise, should also be understood to mean X, Y, Z, or any combination thereof, including “X, Y, and/or Z.”

The systems and methods described herein are not limited to the specific embodiments described herein, but rather, components of the systems and/or steps of the methods may be utilized independently and separately from other components and/or steps described herein.

Although specific features of various embodiments of the disclosure may be shown in some drawings and not in others, this is for convenience only. In accordance with the principles of the disclosure, any feature of a drawing may be referenced and/or claimed in combination with any feature of any other drawing.

This written description uses examples to provide details on the disclosure, including the best mode, and also to enable any person skilled in the art to practice the disclosure, including making and using any devices or systems and performing any incorporated methods. The patentable scope of the disclosure is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims.

What is claimed is:

1. A contact probe comprising:
a shell comprising a first end and an opposed second end, said shell defining an interior chamber therein and a longitudinal axis extending through said first end and said second end;
a plunger partially received within the interior chamber and extending longitudinally outward of said first end, said plunger comprising a tip for electrically connecting said contact probe to an external chip; and
a stepped collar coupled to said shell, said stepped collar comprising a first step and a second step, said second step extending about said shell and said first step extending around said plunger longitudinally between said second step and said tip.

2. The contact probe of claim 1, wherein said first step has a first diameter perpendicular to the longitudinal axis and said second step has a second diameter perpendicular to the longitudinal axis, and wherein the first diameter is less than the second diameter.

3. The contact probe of claim 1, wherein said stepped collar further includes a first axial end on said first step and a second, opposed axial end on said second step, said first step comprising an outer surface extending longitudinally from said first axial end to said second step.

4. The contact probe of claim 3, wherein said first axial end defines a first opening and said second axial end defines a second opening, and wherein said plunger extends through the first opening and said shell extends through the second opening.

5. The contact probe of claim 3, wherein said stepped collar comprises a first interior surface and a second interior surface, said first interior surface extending longitudinally from said first axial end to said second interior surface, said second interior surface extending longitudinally from said first interior surface to said second axial end, and wherein said first interior surface and said second interior surface cooperatively define a slot sized to receive the plunger therein.

6. The contact probe of claim 5, wherein said plunger comprises a neck extending outward of said shell to said tip, and wherein said first interior surface contacts said neck.

7. The contact probe of claim 5, wherein said second interior surface extends circumferentially about said shell radially outward of said first interior surface.

8. The contact probe of claim 1, wherein said stepped collar defines a longitudinally extending slot, and wherein said shell comprises an outer surface received within said slot and a ledge extending radially outward of said outer surface, said ledge being positioned on said shell to contact said first step.

9. The contact probe of claim 1, wherein said plunger further comprises:
a base portion received within the interior chamber;
a shoulder positioned to contact said first end of said shell;
a crown comprising said tip; and
a neck extending from said shoulder to said crown.

10. The contact probe of claim 9, wherein said stepped collar further comprises an interior surface that engages said neck, and wherein said crown extends radially outward of said neck.

11. The contact probe of claim 1, wherein said plunger is a first plunger and said tip is a first tip, and wherein said contact probe further comprises:
a second plunger at least partially received within the interior chamber and extending longitudinally outward of said second end, said second plunger comprising a second tip for electrically connecting said contact probe to a conductive pad; and
a biasing element connecting said first plunger to said second plunger.

12. The contact probe of claim 1, wherein said stepped collar is a first collar, and wherein said contact probe further comprises a second collar coupled to said shell longitudinally between said second end and said stepped collar.

13. The contact probe of claim 1, wherein said stepped collar is formed of an insulative material.

14. An electrical connector assembly comprising:
a socket body comprising a neck and a central portion extending within said socket body and cooperatively defining a cavity therein; and
a contact probe at least partially positioned within the cavity, said contact probe comprising:
a shell comprising a first end and an opposed second end, said shell defining an interior chamber therein and a longitudinal axis extending through said first end and said second end;
a plunger partially received within the interior chamber and extending longitudinally outward of said first end, said plunger comprising a tip for electrically connecting said contact probe to an external chip; and
a stepped collar coupled to said shell, said stepped collar comprising a first step sized in correspondence with said neck and a second step sized in correspondence with said central portion.

15. The electrical connector assembly of claim 14, wherein said first step has a first diameter perpendicular to the longitudinal axis and said second step has a second diameter perpendicular to the longitudinal axis, and wherein the first diameter is less than the second diameter.

16. The electrical connector assembly of claim 14, wherein said stepped collar further includes a first axial end on said first step and a second, opposed axial end on said second step, said first step comprising an outer surface extending longitudinally from said first axial end to said second step.

17. The electrical connector assembly of claim 16, wherein said first axial end defines a first opening and said second axial end defines a second opening, and wherein said plunger extends through the first opening and said shell extends through the second opening.

18. The electrical connector assembly of claim 16, wherein said stepped collar comprises a first interior surface and a second interior surface, said first interior surface extending longitudinally from said first axial end to said second interior surface, said second interior surface extending longitudinally from said first interior surface to said second axial end, and wherein said first interior surface and said second interior surface cooperatively define a slot sized to receive the plunger therein.

19. The electrical connector assembly of claim 18, wherein said plunger comprises a neck extending outward of said shell to said tip, and wherein said first interior surface contacts said neck.

20. A method of forming a contact probe comprising:
providing a shell including a first end and an opposed second end, the shell defining an interior chamber therein and a longitudinal axis extending through the first end and the second end;
positioning a plunger at least partially within the interior chamber, the plunger extending longitudinally outward of the first end to a tip for electrically connecting the contact probe to an external chip; and
coupling a stepped collar to the shell, the stepped collar including a first step and a second step, the second step extending about the shell and the first step extending around the plunger longitudinally between the second step and the tip.
